(19) United States
(12) Patent Application Publication
(10) Pub. No.: US 2011/0001230 A1
(43) Pub. Date: Jan. 6, 2011

(54) Systems and Methods of Improved Heat Dissipation with Variable Pitch Grid Array Packaging

(75) Inventors: Jianjun Li, Holmdel, NJ (US); Robert W. Warren, Newport Beach, CA (US); Nic Rossi, Causeway Bay (HK)

Correspondence Address: CONEXANT SYSTEMS, INC, LEGAL DEPARTMENT - ATTN: LUCY COONEY, 4000 MacArthur Blvd., Mail Stop K02-239, Newport Beach, CA, 92660, US

(73) Assignee: CONEXANT SYSTEMS, INC., Newport Beach, CA (US)

(21) Appl. No.: 12/497,241

(22) Filed: Jul. 2, 2009

(51) Int. Cl. H01L 23/498; H01L 21/56

(52) U.S. Cl. 257/693; 438/124; 257/E23.069; 257/E21.502

(57) ABSTRACT

Adequate heat dissipation is essential for semiconductor devices. When a device exceeds a specified junction temperature, the device can be damaged, not perform correctly, or can have a reduced operating life. Semiconductor packages must dissipate heat from the chip to the external environment (i.e. to the PCB, air, etc) to keep the semiconductor device below a certain temperature threshold. For most devices, the most efficient way to dissipate the heat is through the package external I/O connections and into the PCB that it is mounted to. For Ball Grid Array (BGA) packages, the external I/Os are solder balls. Variable pitch packages pose advantages in heat dissipation without introducing significant costs.

### BACKGROUND OF THE INVENTION

1. Field of the Invention

The present invention relates generally to semiconductor packaging and specifically to the use of variable pitch interfaces.

2. Related Art

Due to the need for more input-output (I/O) interfaces with modern integrated circuits (IC), IC packaging has evolved from dual inline pin (DIP) packaging where pins are available only on the perimeter to pin grid arrays (PGA), where pins are available in a grid pattern under the package. The pins in a PGA are used to conduct electrical signals from the integrated circuit to a printed circuit board, and vice versa. Rather than having long pins, a ball grid array BGA packaged replace the pins with balls of solder attached to the bottom of the package which conduct the electrical signals to and from the printed circuit board PCB. The matching PCB has conductive pads in a pattern that matches the solder balls. When the package is heated the solder melts and couples the package to the PCB. When the package cools, the solder solidifies completing the assembly.

A BGA package offers high density connections especially as technology miniaturizes. As the density of output pins increases, older technologies such as DIP and PGA have to package pins closer together making assembly more difficult. Soldering a high density of pins can lead to a higher probability of shorting adjacent pins if the solder overflows. BGAs avoid this short coming because the solder in the forms are of a proscribed size and prepositioned on the package.

Because the output conductors are much shorter than in pin based packages, BGA have lower inductance. Inductance in a package can cause unwanted signal distortion especially in high speed applications. Another advantage of BGA packages over pin based packages offers lower thermal resistance between the package and the PCB. This allows greater conduction of heat away from the integrated circuit aiding in the prevention of overheating.

An integrated circuit can be connected to the balls either through wire bond or by flip-chip connections. FIG. 1 illustrates a cross-section of a typical wire bonded BGA package. Fabricated die 102 is attached with die attach 104 to substrate 106. Electrically, fabricated die 102 is accessed through wire bond 108 through bond pad 110. Wire bond 108 is connected also connected to substrate 106 through a metal trace such as metal trace 112. In some packages, substrate 106 could comprise multiple layers and contain additional metal traces for routing, but in this illustration, substrate 106 is a multiple layer. Metal traces 112 is connected through via 114 to a bond finger such as metal trace 116. Metal traces on the bottom of the substrate such as metal trace 116 comprises a solder pad such as solder pad 118 where a solder ball such as solder ball 120 can be attached at the factory. Solder mask 122 covers the metal traces on the bottom of the substrate but leaves openings exposing the solder pads such as solder pad 118. Mold compound 130 fills in the package.

Typically, the vias such as via 114 are drilled into the substrate and a metal or conductor is coated along the wall of the via to maintain electrical contact between metal trace 112 and metal trace 116. For this purpose it is not necessary to completely fill the via with a conductor.

In addition to making electrical contact with a fabricated die, solder balls, and vias through substrate 106 can also be used for thermal purpose. For example, via 124 is in thermal contact with fabricated die 102. It is also coupled to solder pad 126 and solder ball 128. In this circumstance, via 124 also serves as a thermal via. A via can be used as either an electrical via, thermal via or both. A thermal via could be completely filled with a thermal conductor such as a metal. This provides better thermal conduction than if the via were simply coated with the thermal conductor. Consequently, the via would then be filled with solder mask material.

Interface pads such as interface pad 118 that are electrically coupled are usually coupled to a metal trace in a printed circuit board where the signals or electricity can be coupled to other components. In the case of BGA packaging, the interface pads are called solder pads. The solder balls such as solder ball 128 which can be used for thermal purposes are often coupled to a single common metal line. In fact, typically this metal line is a ground plane on the PCB.

FIG. 2 shows in greater detail metal traces on the surface of the substrate. Some exemplary traces are shown as metal trace 112 on top of substrate 106. The position of die 102 is also indicated. In the detailed view regions 202 show where the wire bond can attach to the metal trace. Regions 204 show the location of the vias such as via 114 which lay underneath the metal traces.

FIG. 3 shows in greater detail metal traces on the bottom of the substrate. Six exemplary metal traces are shown as metal traces 116. Each comprises a solder pad shown as 118. Regions 302 show areas underneath vias.

FIG. 4 shows a corresponding section of solder mask 122 covering the metal traces shown in FIG. 3. Solder mask 122 covers the metal traces on the bottom of the substrate, but leaves openings for the solder pads.

FIG. 5 illustrates an alternate BGA package known as a cavity down BGA package. Fabricated die 502 is attached with die attach 504 to slug 506 which is often made of copper. This configuration is an up-side down compared to that of FIG. 1. Wire bond 510 connects to fabricated die 502 through bond pad 508. Wire bond 510 also connects to laminate 512. Laminate 512 comprises metal trace 514 and via 516. Wire bond 510 specifically connects to metal trace 514. Via 516 connects metal trace 514 to solder pad 518 and solder ball 520. A lid or liquid encapsulant (522) completes the package.

FIG. 6 illustrates a BGA package using a flip-chip attachment. Fabricated die 602 is attached to multilayer substrate 606 Flip-chip attachment not only provides a physical attachment of fabricated die 602 to multilayer substrate 606 it also provides electrical contact between fabricated die 602 and multilayer substrate 606. Rather than wire bonds, fabricated die 602 is attached to vias pads 620 using bumps 604. Via pads 620 in turn are attached to vias shown here by vias 610. After the interface between fabricated die 602 and substrate 606 including bumps 604 are encased by underfill 622. This package uses metal traces 608 and additional vias 624 to route electrical signals from fabricated die 602 to solder pad 612 through substrate 606. Solder balls 614 are attached to solder pad 612 in the factory. The package is completed with thermal grease 616 and metal lid 618. Although perhaps a little more complicated to implement, thermal interfaces can also be used in cavity BGA and flip-chip attached BGA packaging as well.

FIG. 7 shows an exemplary solder ball pattern for a BGA package. Substrate 702 is shown comprising a plurality of solder pads 704. On each solder pad is a solder ball, represented by solder balls 706 in the figure. In this particular example, solder balls do not cover the entire base of the substrate. For some forms of BGA packaging, this is preferable. FIG. 8 shows another solder ball pattern for a BGA package. Substrate 802 is shown comprising a plurality of solder pads represented by solder pads 804. On each solder pad is a solder ball 806. In the breakout view, some solder pads are shown without a solder ball for clarity. Furthermore for clarity, only the solder pad left exposed by the solder mask is shown. It should be understood in this and subsequent diagrams that a solder mask may be present exposing only the solder pads in the metal trace layer above. Each solder pad has a relatively uniform diameter shown at 808. Each solder ball also has an essentially uniform diameter shown at 810. In addition, the distance between the centers of adjacent solder balls or equivalently solder pads is referred to as the pitch.

It is worth mentioning that there are also non-solder mask defined BGA packaging. The key difference between a non-solder mask defined BGA is that the opening in the solder mask does not define the exposed extent of the solder pad. FIG. 9A shows a close-up view of the solder mask defined BGA package. This is essentially the same as those described above. Solder pad 902 provides a contact point for solder ball 904. Solder mask defined 906 provides an opening for solder ball 904. The solder ball can in fact fill the entire opening provided by solder mask 906.

FIG. 9B shows a close-up view of a non-solder mask defined BGA package. Unlike the solder mask defined BGA package, solder ball 914 sits and potentially surrounds solder pad 912. In this case, solder mask 916 has openings larger than the solder pads. Whether using solder mask defined BGA or non-solder mask defined BGA, the principles discussed relating to thermal conduction still apply.

While using thermal vias to draw heat from the fabricated die, can aid in heat dissipation, it has its limitations. First, the number of solder pads available for thermal purposes is limited by the number of solder pads needed for electrical connections to the fabricated die. So if there are 100 solder pads, but 88 are needed for electrical connections then only 12 are available for thermal purposes. The number of solder pads can be increased by reducing the pitch. However, this can pose challenges that increase the cost of the packaging as well as the PCB used to communicate with the package, because finer dimensioned traces and vias much be used for routing. Assembly of finer pitch BGAs can also be more challenging to lower yields caused by shorts or open circuits.

Other methods have tried to address the heat dissipation problem by adding heat spreaders to the package, by using higher thermal conductivity mold compounds, increasing the package layer count or size, or by using higher thermal conductivity die attach epoxies. In some extreme cases the die size is increased to improve the heat dissipation. However, these attempts are very costly and impact negatively product margin, plus they have proven to affect device reliability. Thus there is a need in the industry for inexpensive packaging techniques to improve heat dissipation.

### SUMMARY OF INVENTION

In an arrayed interface package such as BGA, PGA, column grid array (CGA) and land grid array (LGA), the pitch of the interfaces can be arrayed. A semiconductor package comprises a fabricated die attached to a substrate. The top surface of the substrate contains metal traces usually used to conduct electrical signals to vias in the substrate. The bottom surface of the substrate also contains metal traces which connect the vias to the interfaces which can be a pin or a solder pad. The interfaces can be spaced out in at least two pitches. Optionally, a solder mask is applied to the bottom of the substrate to prevent shorting. The solder mask have openings corresponding to the solder pads. If the solder pads have variable pitch so do the solder mask openings. Solder balls can then be placed on the solder pads. The pitch of the solder balls is the same as that of the corresponding solder pads.

Typically, electrical vias or vias used to conduct electrical signals only have their walls coated with conductor. In contrast, thermal vias are filled with conductor to enable them to conduct more heat away from the die. Additionally, solder pads coupled to thermal vias can be packed more densely together and thus make ideal candidates for higher pitch interfaces.

Additional package types can also exploit the variable pitch array layout include flip-chip BGA, cavity down BGA, PGA and LGA.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF DRAWINGS

FIG. 1 illustrates a cross-section of a typical wire bonded BGA package;

FIG. 2 shows in greater detail metal traces on the surface of the substrate;

FIG. 3 shows in greater detail metal traces on the bottom of the substrate;

FIG. 4 shows a corresponding section of a solder mask covering the metal traces shown in FIG. 3;

FIG. 5 illustrates an alternate BGA package known as a cavity BGA package;

FIG. 6 illustrates a BGA package using a flip-chip attachment;

FIG. 7 shows an exemplary solder ball pattern for a BGA package;

FIG. 8 shows another solder ball pattern for a BGA package;

FIG. 9A shows a close-up view of the solder mask BGA package;

FIG. 9B shows a close-up view of a non-solder mask BGA package;

FIG. 10 shows a bottom view of a package with variable pitch I/O interfaces;

FIG. 11 illustrate a cross section of a package where different ball sizes are used;

FIG. 12 illustrates a cross section of a package having where the same ball size is used for the two pitches shown;

FIG. 13 illustrates a cross section of a package where the larger of the two ball sizes if interfaces in the finer pitch are used for thermal purposes;

FIG. 14 illustrates a metal trace which comprises a plurality of solder pads in the fine pitch region of a variable pitch package;

FIG. 15 shows a metal trace comprising overlapping solder pads;

FIG. 16 shows an example of two regions where finer pitch is used;

FIG. 17 shows a hypothetical example of utilizing variable pitch to relax the routing requirements on the die; and

FIG. 18 shows a flow chart illustrating the process for creating a package with a variable pitch interface.

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

### DETAILED DESCRIPTION

A detailed description of embodiments of the present invention is presented below. While the disclosure will be described in connection with these drawings, there is no intent to limit it to the embodiment or embodiments disclosed herein. On the contrary, the intent is to cover all alternatives, modifications and equivalents included within the spirit and scope of the disclosure as defined by the appended claims.

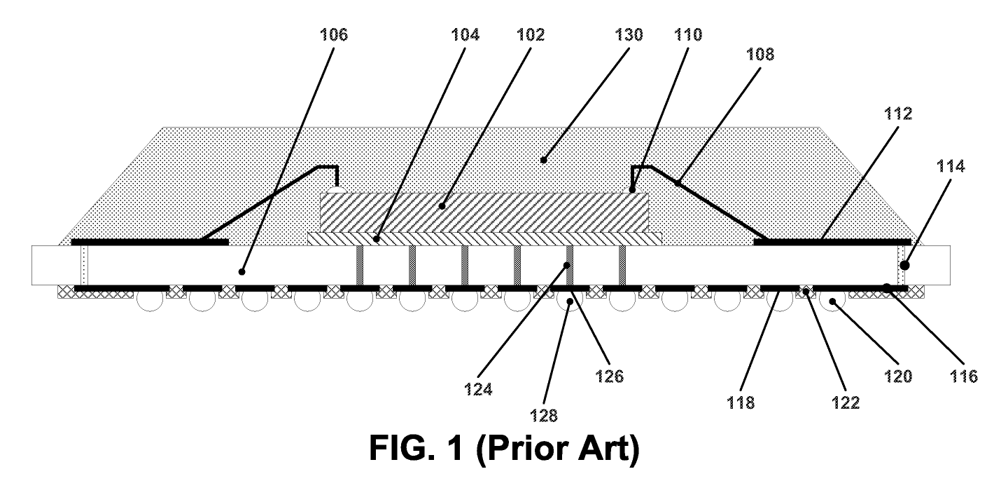

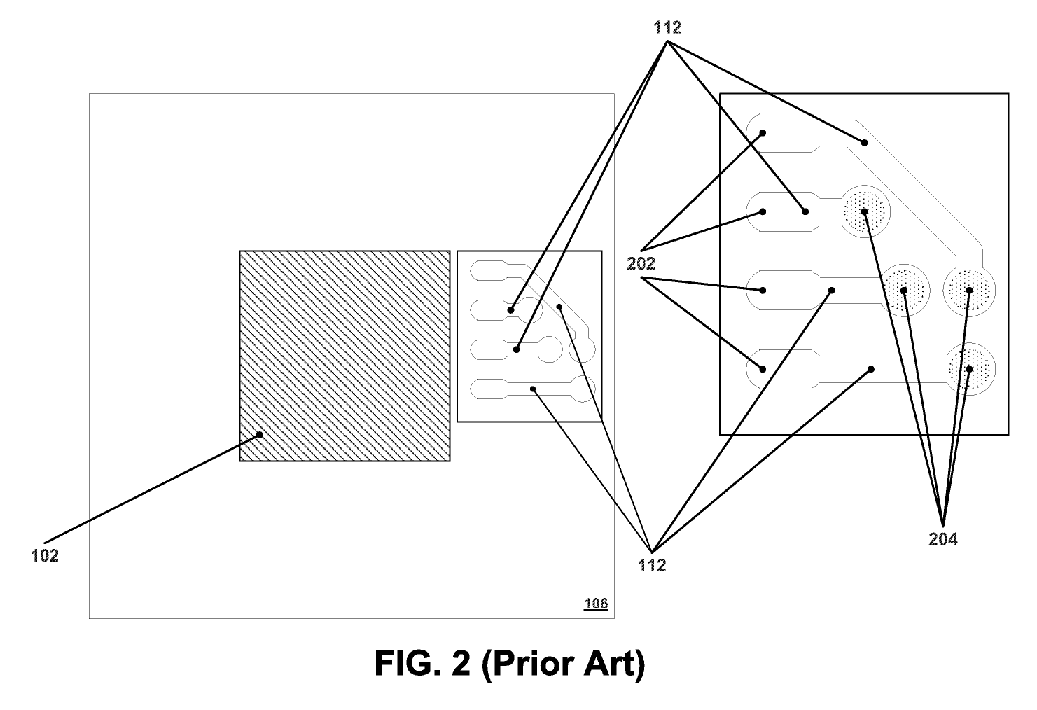

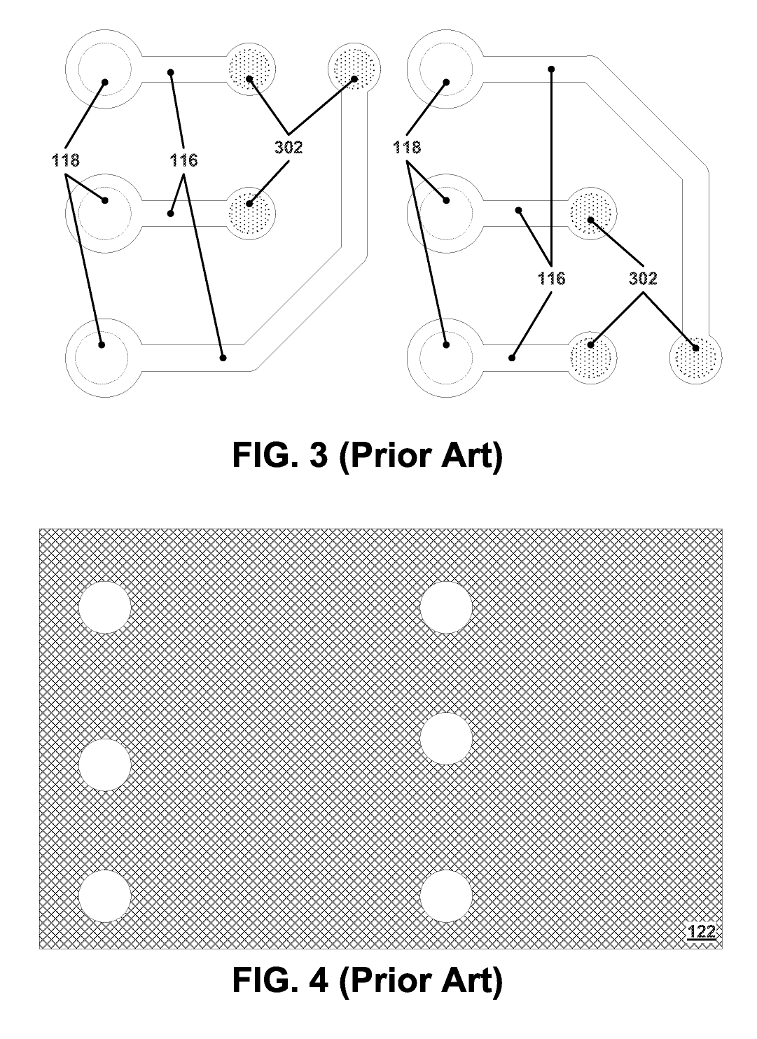

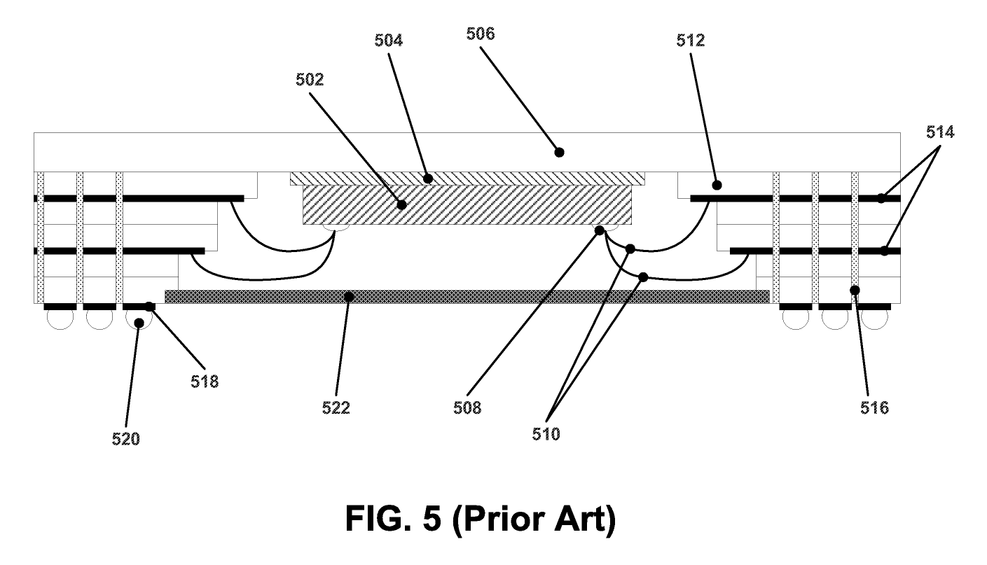

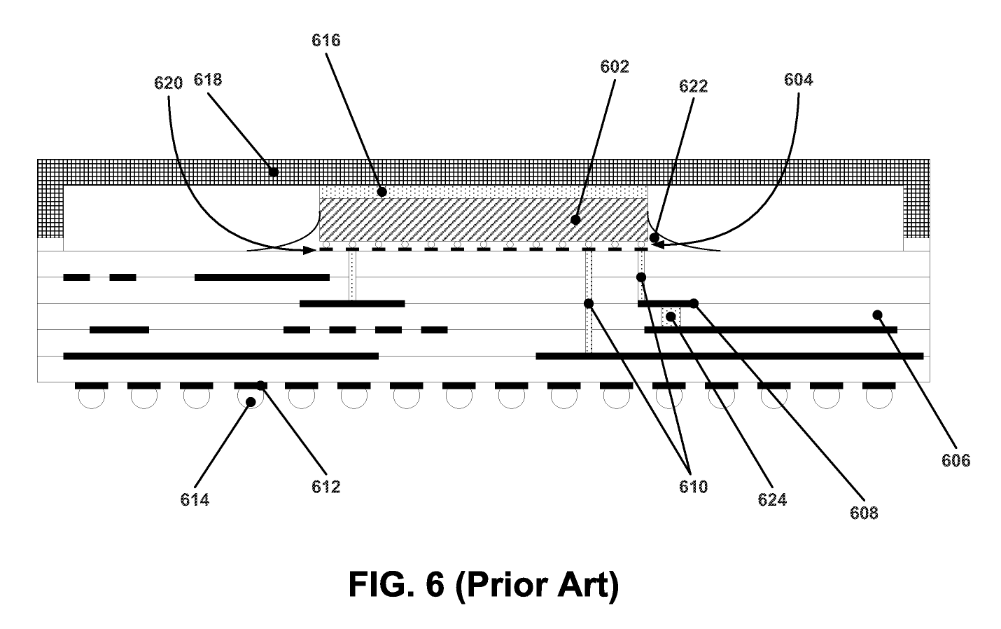

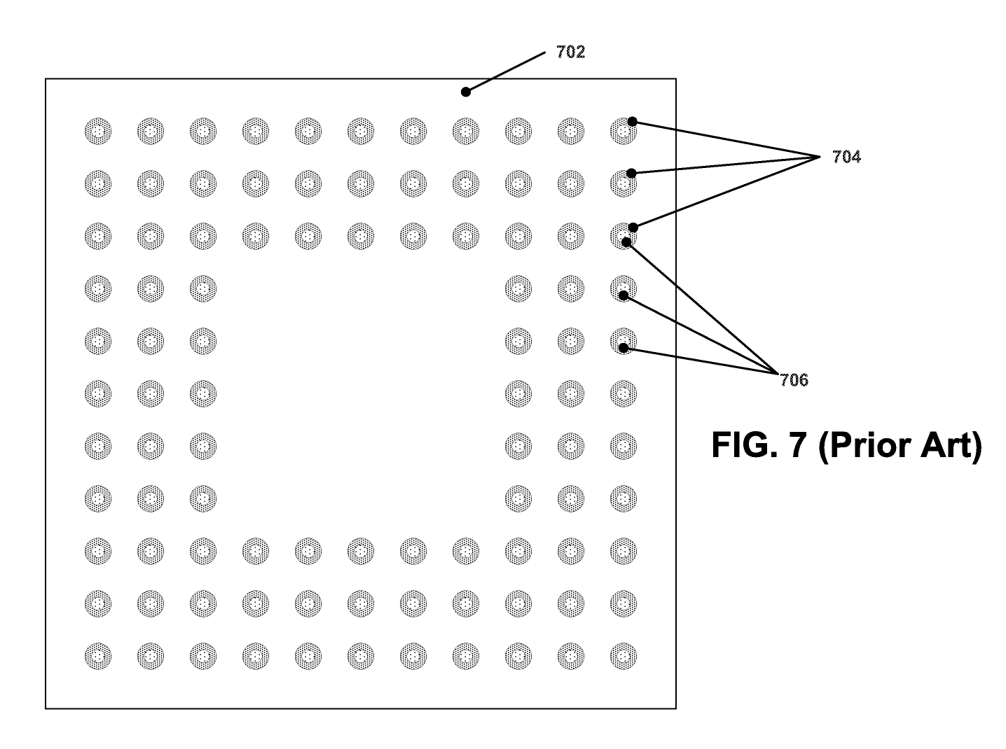

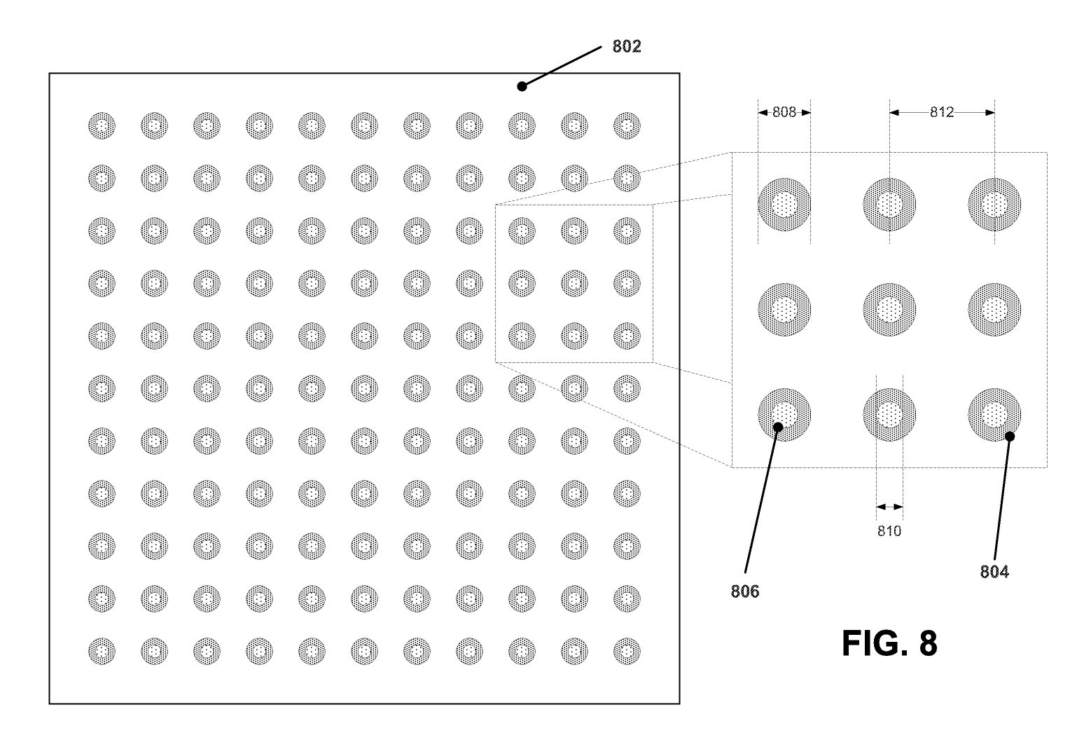

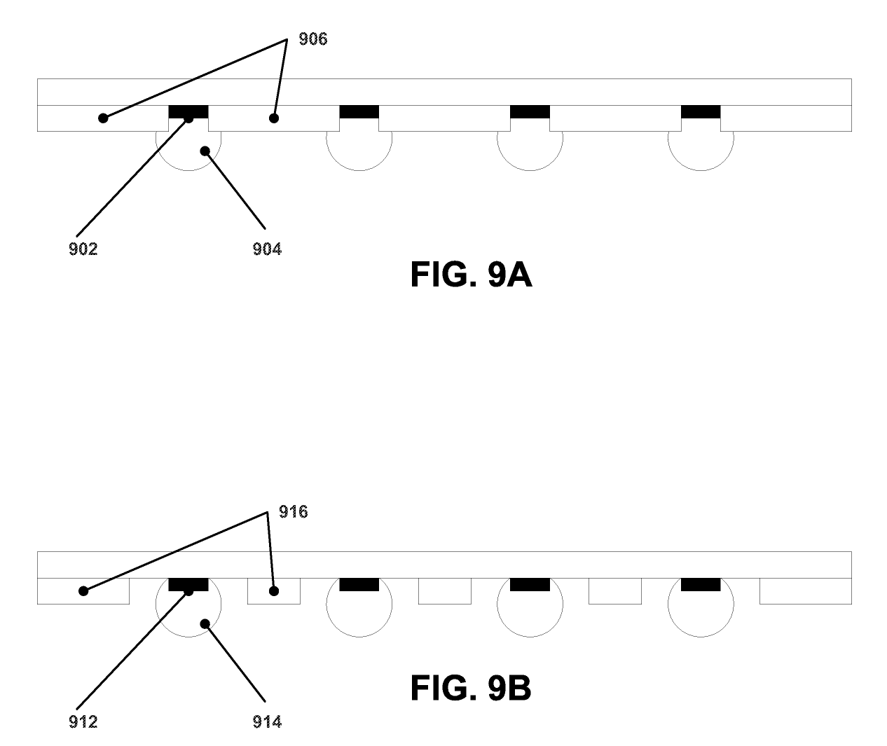

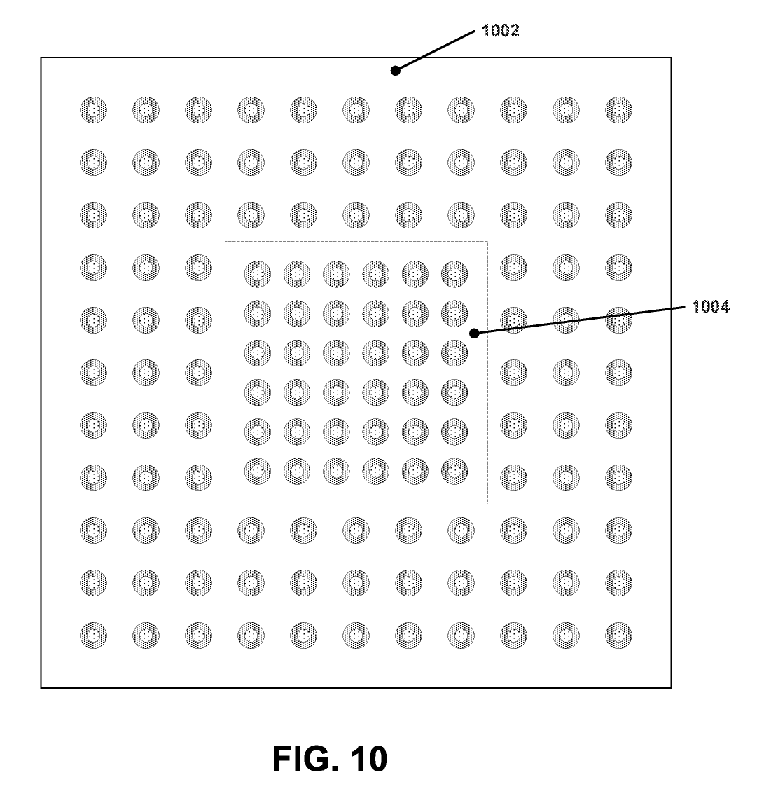

FIG. 9 shows a bottom view of a package with variable pitch I/O interfaces. The package can be any one of the array technologies such BGA, PGA and/or LGA, but for the purposes of here, the example of BGA is used. Furthermore, packaging akin to that described for FIG. 1 is used as an example. However, one of ordinary skill in the art would appreciate its applicability to alternate array packages such as PGA and LGA as well as different BGA configurations such as CBGA and flip-chipped BGA.

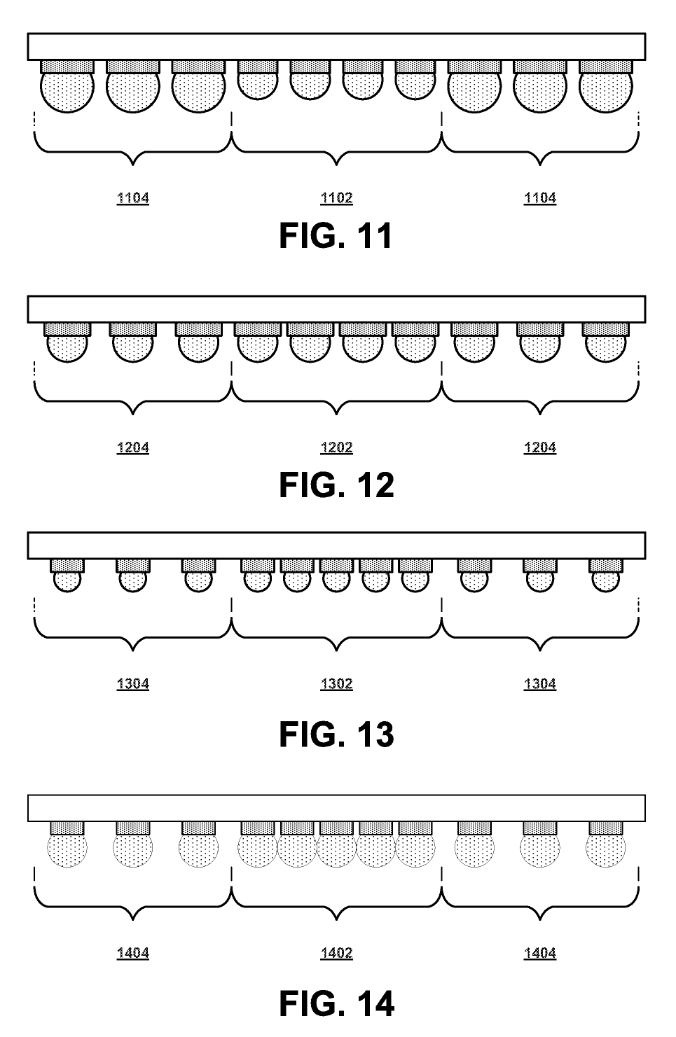

In FIG. 11 region 1104 lies most directly underneath the fabricated die. In a multiple layer substrate, such as shown in FIG. 1, the area under the fabricated die is the least desirable for routing electrical signal but the most desirable for thermal conduction. A finer pitch array underneath the fabricated die allows for a greater amount of solder balls per unit area, which increases the thermal conductivity paths from the die into the PCB that it is mounted to. Outside region 1104, a grosser pitch is used that allow for more economical electrical routing. Because the pitch is wider, trace width, trace spacing, and plated through-hole via sizes for the PCB can be larger which leads to higher assembly yields.

One difficulty with using variable pitch is that in order to allow for 2^{nd} level assembly, the solder ball sizes must be the same size. FIG. 11 illustrate a cross section of a package where different ball sizes are used. Supposed balls in region 1102 having a coarser pitch are larger than balls in region 1104 which has a finer pitch. Because of the difference in diameter of the balls, either the smaller balls do not make contact with the PCB below defeating the purpose of the thermal conduction by the balls or the balls in region 1102 are compressed so much during the attachment process that the solder could spill over and make electrical contact with adjacent solder balls. Thus for this type of packaging to be effective a uniform solder ball planarity should be maintained.

Typically, a given ball size is recommended for grid array pitches of a certain range. For example, typically the same ball size is used for 0.8 mm and 1.0 mm pitch. For example, 500 or 600 μm solder balls can typically be used in either 0.8 mm or 1.0 mm pitch applications. Since the pitch size is proportional to the square of ball count, the 0.8 mm pitch used for thermal dissipation allows for over 40% increase in ball count. FIG. 12 illustrates a cross section of a package having where the same ball size is used for the two pitches shown. In region 1202, a finer pitch is used such as 0.8 mm. In region 804, a coarser pitch is used such as 1.0 mm.

While in FIG. 12, the same ball size is recommended for pitches in region 1202 and region 1204, if higher densities of balls are needed in a particular region the ball size recommended for the finer pitch can be used. FIG. 13 illustrates such an example, in region 1302 a pitch even finer than that shown in FIG. 12 is used. Normally, an even smaller ball size would be recommended for the finer pitch. However, the smaller ball sizes suffer from lower reliability due to thermal fatigue, and packages using the smaller ball sizes have a higher failure rate in a drop test. In order to avoid the situation shown in FIG. 11, this smaller ball size would could then be used for all region including region 1304 which has a coarser pitch and would normally use a recommended larger ball size.

The main rationale for the using the smaller of the two ball sizes recommended for each respective region is to avoid electrical contact between solder balls when they are heated and attached to the PCB. This would prevent short circuits. However, as shown in FIG. 14, the larger of the two ball sizes may be used if region 1402 with the finer pitch is used for thermal purposes. The larger ball size would facilitate greater thermal conduction than the smaller ball size. Because the solder balls and corresponding vias in region 1402 are used solely for thermal purposes, contact between adjacent solder balls would not have a negative impact.

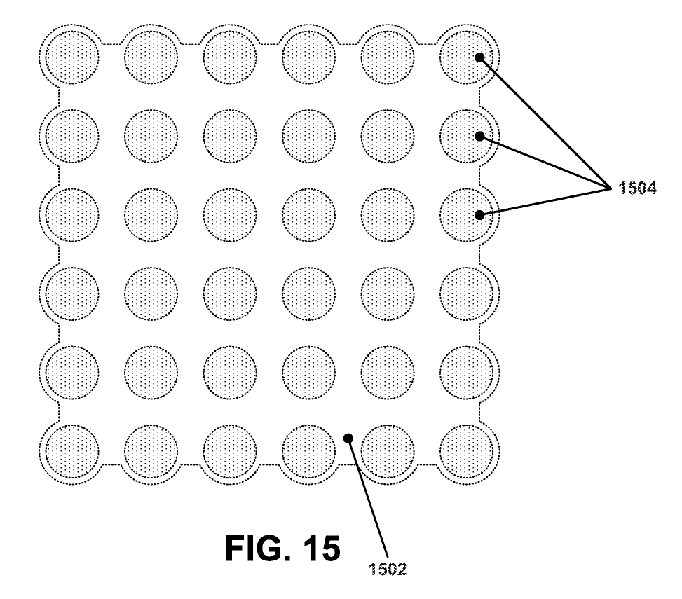

Another difficulty with the use of fine pitch arrays in general is that the metal traces such as the traces on the bottom surface of the substrate have to have finer lines and additionally the solder pads potentially has smaller spacing between them. Resulting in lower yields and/or higher packaging costs. However, if the fine pitch region of a variable pitch package is used purely for thermal purposes there is no need to maintain separate metal traces for each solder pad. FIG. 15 illustrates a metal trace which comprises a plurality of solder pads in the fine pitch region of a variable pitch package. Metal trace 1502 in this example actually comprises all the solder pads in the fine pitch region. The regions indicated by openings 1504 represent the openings left by the solder mask. (For clarity only some of the openings are labeled). Because for thermal purposes, there is no need to separate electrically the solder pads a single metal trace or several large metal traces can comprises the solder pads in the fine pitch region. If some electrical interfaces are needed in the fine pitch region, then the corresponding solder pads can be formed from metal traces separate from those used for thermal interfaces.

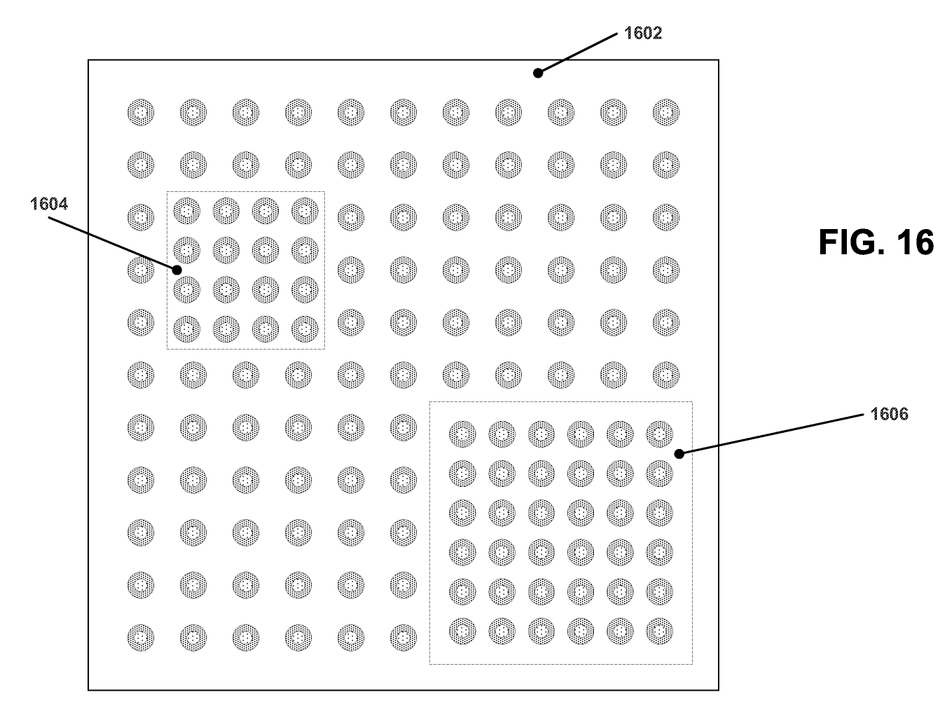

While the examples above imply the use of finer pitch in the center region, the use of varied pitch can be applied anywhere on the bottom of the package. FIG. 16 shows an example of two regions where finer pitch is used. Specifically regions 1604 and 1606 have finer pitch than the rest of the solder pads/solder balls on the rest of substrate 1602. The two regions could represent the substrate underneath two separate dies in a multiple die package. While not necessary, placement of thermal vias under attached dies is a very efficient placement of solder balls for cooling. Therefore, if dies are attached above regions 1604 and 1606, a finer pitch array of solder balls could better facilitate cooling.

Electrically variable pitch packaging could also be useful. Typically, the bond pads are essentially equally spaced on the surface of a die. Internal circuitry in the die must route signals to their respective bond pads. In order to meet the requirements posed by the bond pads, additional routing in terms of metal lines may be required. However, if these requirements are relaxed, the amount of in the die routing could potentially be reduced. In fact, it may be possible that layers of metal lines could be eliminated, reducing the cost to fabricate a die and/or substrate.

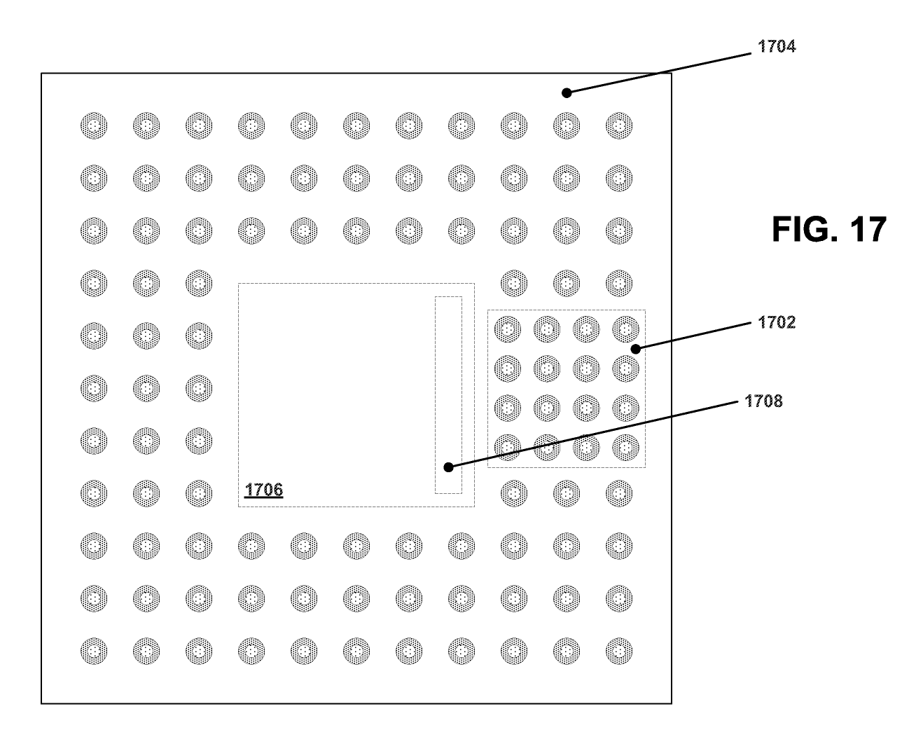

FIG. 17 shows a hypothetical example of utilizing variable pitch to relax the routing requirements on the die. In this example, die 1706 is shown in outline. For clarity any solder pads and solder balls under die 1706 are not shown. For example, die 1706 device may require 100 bond pads on each side of the die except in region 1708 where it may require 150. This can cause routing difficulty on the side near region 1708 because it will require additional I/Os that aren't available on that package side. Traditionally, the only option left to the designer, short of using a finer pitch throughout the package to obtain extra interfaces, is to borrow package interfaces (e.g. solder balls) from the other sides of the package and route I/Os to the borrow interfaces. Instead, additional interfaces are provided in region 1704 by using a finer pitch, making routing easier, and since the traces will not need to be routed to the other side of the package, trace resistance and inductance are lower and performance won't be degraded. The unbalanced I/O situation can surface in particular in multichip packages. Because fine pitch is used in only part of the of the package, the higher tolerance requirements imposed by the fine pitch interfaces apply only to a portion of the package, hence making it easier to fabricate over a package with fine pitch.

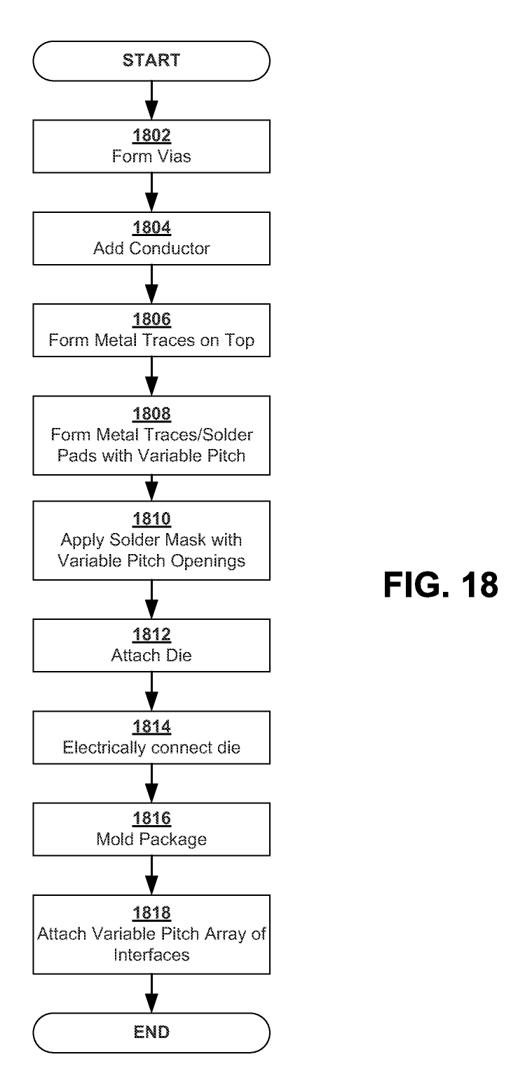

FIG. 18 shows a flow chart illustrating the process for creating a package with a variable pitch interface. One of ordinary skill in the art will note that not all steps need to performed in the order described and that many steps can be performed in a different order. At step 1802, vias a formed in a substrate. This is typically performed by drilling. At step 1804, a conductor material is applied to the via. In the case of electrical vias the conductors typically coat the walls of the via and in the case of thermal vias the conductors fill the via. At step 1806, metal traces are formed on top of the substrate which provide a site for a wire bond and are connected to at least some of the vias. At step 1808, metal traces are formed on the bottom of the substrate where the metal traces comprise interface pads in an array. The interface pads comprise at least two regions, a coarse region where the interface pads are farther apart and a fine region where the interface pads are closer together. At step 1810, a solder mask is applied to bottom of the substrate with openings exposing the interface pads in the coarse region and interface pads in the fine region. At step 1812, the die is attached to the substrate. At step 1812 wire bonds are attached to the bond pads on the die and to the metal traces on top of the substrate. Alternatively, the die can be flip-chipped onto the via pads or metal traces on top of the substrate. At step 1814, a mold compound is used to encapsulate the die, wire bond and the top of the substrate. At step 1818 an array of interfaces such as solder balls are attached to the interface pads, wherein the solder balls are spaced closer together in the fine region and farther apart in the coarse region. In the case of PGA, an array pins can be attached to the interface pads. In the case of CGA, an array of columns can be attached to the interface pads. In the case of LGA, the interface pads themselves are the interfaces.

Because the manufacturing technique to apply variable pitch interfaces uses existing fabrication technology and only calls for a modification of the design of the metal trace layer below the substrate, the placement of the interface pads, a modification of the design of the solder mask and the placement of the interfaces, no significant additional fabrication cost is incurred. A 2-5% improvement in package thermal dissipation has been observed using a variable pitch BGA package. Though the thermal improvement may seem small, this difference could affect package costs by 5-15%, and/or affect the amount of functionality or speed that a device can accommodate.

As mentioned before in addition to the multiple layer substrate BGA as shown, variable pitch interfaces can be used in any packaging technology that uses arrays of interfaces such as other types of BGA described above as well as PGAs and LGAs.

It should be emphasized that the above-described embodiments are merely examples of possible implementations. For example, the embodiments described are in the context of BGA, but can equally be applied to PGA, LGA or other packaging using arrayed interfaces. Those skilled in the art should appreciate that they can readily use the disclosed conception and specific embodiment as a basis for designing or modifying other structures for carrying out the same purposes as set herein. Those skilled in the art should understand that they can make various changes, substitutions and alterations herein without departing from the spirit and scope of the invention in its broadest form. All such modifications and variations are intended to be included herein within the scope of this disclosure and protected by the following claims.

1. A semiconductor package comprising:
a semiconductor die;
a substrate having a top surface and a bottom surface, said substrate comprising vias comprising a conductor;
metal traces on the top surface of the substrate;
metal traces on the bottom surface including interface pads
wherein metal traces on the bottom surface couple the interface pads to the vias; and
wherein the bottom surface comprises a first region and a second region and the interface pads in the first region are spaced at a first pitch and the interface pads in the second region are spaced at a second pitch.

2. The semiconductor package of claim 1 further comprising:
a solder mask having an opening under each interface pad; wherein the openings in the solder mask are spaced at the first pitch in the first region and the solder mask are spaced at the second pitch in the second region.

3. The semiconductor package of claim 1 further comprising a solder ball coupled to each interface pad.

4. The semiconductor package of claim 1 wherein the package is a flip-chip BGA.

5. The semiconductor package of claim 1 wherein the package is a cavity down BGA.

6. The semiconductor package of claim 1 wherein the package is a PGA or CGA.

7. The semiconductor package of claim 1 wherein the package is a LGA.

8. The semiconductor package of claim 1 wherein the metal traces on the top substrate comprise bond fingers and wire bonds couple the die to the bond fingers.

9. The semiconductor package of claim 1 wherein the metal traces on the top substrate comprise via pads and the die is flip-chipped to the via pads.

10. The semiconductor package of claim 1 wherein the vias comprise electrical vias and thermal vias and the interface pads in the first region are coupled to electrical vias and interface pads in the second region are coupled to thermal vias.

11. The semiconductor package of claim 10 wherein the electrical vias have walls that are coated with a conductor and the thermal vias are filled with a conductor.

12. A method of packaging a semiconductor die comprising:
creating vias in a substrate having a top surface and a bottom surface and having a first region and a second region;
adding conductor to the vias;
forming metal traces on the top surface;
forming metal traces on the bottom surface, wherein the metal traces comprises interface pads spaced at a first pitch in the first region and interface pads spaced at a second pitch in the second region;
attaching the semiconductor die to the top surface;
electrically connecting the semiconductor die to the metal traces on the top surface; and
encapsulating the package in a mold compound.

13. The method of claim 12, wherein the metal traces on the top surface comprises bond fingers and the electrically connecting comprises attaching wire bonds between the die and the bond fingers.

14. The method of claim 12, wherein the metal traces on the top surface comprises via pads and the electrically connecting comprises flip-chipping the die onto the via pads.

15. The method of claim 12, further comprises forming a solder mask to cover the metal traces on the bottom surface, wherein the solder mask has openings underneath each interface pad.

16. The method of claim 12, further comprises affixing a pin beneath each interface pad.

17. The method of claim 12, further comprising attaching a solder ball to each interface pad.
The method of claim 12, wherein the vias have walls and wherein adding conductor to the vias comprises coating the walls of the vias with a conductor.

18. The method of claim 12, wherein adding conductor to the vias comprises filling the vias with a conductor.

19. A semiconductor package comprising:
a semiconductor die;
a substrate having a top surface and a bottom surface, said substrate comprising vias;
means for electrically connecting the die to the vias;
interface pads on the bottom surface;
means for connecting the interface pads to the vias wherein the bottom surface comprises a first region and a second region and the interface pads in the first region are spaced at a first pitch and the interface pads in the second region are spaced at a second pitch.

20. The semiconductor package of claim 19 further comprising:
a masking means for covering the bottom surface comprising openings beneath each interface pad.
